(19) United States
(12) Patent Application Publication
(10) Pub. No.: US 2010/0080444 A1
(43) Pub. Date: Apr. 1, 2010

(54) PROCESSING APPARATUS, PROCESSING METHOD, METHOD OF RECOGNIZING TARGET OBJECT AND STORAGE MEDIUM

(75) Inventors: Hirofumi Yamaguchi, Nirasaki-shi (JP); Katsuhito Hirose, Nirasaki-shi (JP); Gaku Ikeda, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/614,065

(22) Filed: Nov. 6, 2009

Related U.S. Application Data
(63) Continuation of application No. PCT/JP08/58371, filed on May 1, 2008.

(30) Foreign Application Priority Data
May 8, 2007 (JP) 2007-123265
Jan. 24, 2008 (JP) 2008-013900

(51) Int. Cl. G06K 9/00; H01L 21/68

(52) U.S. Cl. 382/144; 700/114

(57) ABSTRACT

A CCD detector 30 captures an image of an arc shape of an outer periphery of a semiconductor wafer W that is on standby position W1 close to an inlet of a processing unit 1. A calculation unit 40 detects, from the captured image of the arc shape, positional data on multiple positions of the shape, obtains a phantom circle of the semiconductor wafer W, calculates center coordinates of the phantom circle, and calculates “information on positional displacement” of the semiconductor wafer W at the standby position W1. A controller 50 controls a transfer unit 12 based on the “information on displacement” to correct the position of the semiconductor wafer W on the processing unit 1.

This application is a Continuation application of PCT International Application No. PCT/JP2008/058371 filed on May 1, 2008, which designated the United States.

### FIELD OF THE INVENTION

The present invention relates to a processing apparatus and method for processing a target object to be processed such as a semiconductor wafer or the like, a method of recognizing the target object and a storage medium.

### BACKGROUND OF THE INVENTION

Recently, a demand for high speed of semiconductor devices, high integration as well as miniaturization of wiring patterns requires improvement of device characteristics and, therefore, there is used a multi-chamber type processing apparatus capable of performing a plurality of processes while maintaining a vacuum state throughout the processes (e.g., Japanese Patent Laid-open Application No. 2003-59861).

A multi-chamber type processing apparatus is formed by connecting a plurality of processing units to polygonal sides of a transfer chamber via respective gate valves. Each of the processing chambers communicates with the transfer chamber by opening a corresponding gate valve, and does not communicate with the transfer chamber by closing the corresponding gate valve. Installed in the transfer chamber is a transfer unit for loading and unloading a semiconductor wafer into and from the processing units. The semiconductor wafer can be loaded and unloaded into and from each processing unit by the transfer unit while maintaining the vacuum state in the transfer chamber and the processing chambers. The transfer unit is arranged substantially at the center of the transfer chamber and includes a support arm for supporting the semiconductor wafer, the support arm being attached to the leading end of a rotatable and extensible/contractible portion.

When the semiconductor wafer is loaded into a processing unit, the semiconductor wafer supported by the support arm of the transfer unit is moved to a predetermined position close to an inlet of the processing unit in the transfer chamber, and then the support arm is moved into the processing unit to mount the semiconductor wafer on a processing plate. In that case, as shown in FIG. 1, the semiconductor wafer is transferred onto a predetermined processing plate in the processing unit while being supported at a predetermined position of the support arm in the transfer chamber.

However, the semiconductor wafer may be displaced with respect to the support arm while being transferred in the previous processing unit or while being slid on the support arm, or the support arm itself may be displaced. In that case, the semiconductor wafer which needs to be positioned at a predetermined position in the transfer chamber before being loaded into the processing unit is displaced as indicated by a phantom line shown in FIG. 1. If the semiconductor wafer being displaced is loaded into the processing unit, the semiconductor wafer is also displaced from the predetermined position on the processing plate in the processing unit, so that desired processing may not be performed.

In order to prevent the above-described problems, when the position of the semiconductor wafer which is just about to be loaded into the processing unit is displaced as indicated by a phantom line shown in FIG. 2, it is required to detect “information on positional displacement” by using a certain device and feed the detected information to a controller of the transfer unit to correct the positional displacement. Specifically, the “information on positional displacement” of the semiconductor wafer which is just about to be loaded into the processing unit is detected, and the transfer unit is controlled to position the semiconductor wafer at a predetermined position on the processing plate in the processing unit based on the detected information.

There is a known apparatus for detecting a position of a semiconductor wafer and correcting the position thereof, in which three line sensors are used (Japanese Patent Laid-open Application No. 2002-43394). In this apparatus for detecting a position of the semiconductor wafer by using the three line sensors, when the semiconductor wafer is positioned at a predetermined position close to an inlet of each processing unit, central coordinates of the semiconductor are calculated by detecting three positions at the periphery of the semiconductor wafer. The “information on positional displacement” of the semiconductor wafer with respect to the support arm is obtained based on the positional displacement of the central coordinates.

However, the line sensors may not have a linear relationship between light-receiving amount and output, and a long adjustment time is required to obtain desired detection accuracy. Further, a temperature range within which the line sensors can be used is narrow, so that they cannot be used in a chamber which needs to be heated.

Moreover, the multi-chamber type processing apparatus has a number of, e.g., four processing units. However, it is difficult to provide a three line sensor displacement system for each of the four processing units due to a space limit. Accordingly, although “information on positional displacement” of a semiconductor wafer, which is unloaded upon completion of processing in a certain processing unit, with respect to a blade (support arm) can be detected at a position close to the inlet of that processing unit, it may not be detected at its neighboring processing unit. Therefore, some of the processing units may have to utilize the “information on positional displacement” of the other processing unit equipped with the sensor. In this method, however, it may not be possible to detect positional displacement of the semiconductor wafer on the support arm which may occur during the transfer from one processing unit to another.

### SUMMARY OF THE INVENTION

An object of the present invention is to provide a processing apparatus and method which can process a target object to be processed in a state where positional displacement is minimized by detecting information on positional displacement of the target object loaded into a processing unit by using a small number of detectors.

Another object of the present invention is to provide a method of recognizing a target object for use in the processing apparatus.

Still another object of the present invention is to provide a storage medium storing a program for performing the method of recognizing a target object to be processed.

In accordance with a first aspect of the present invention, there is provided a processing apparatus including: at least one processing unit; a transfer chamber including a transfer unit for loading and unloading a circular target object to be processed into and from the processing unit; an image pickup device for detecting positional data on multiple positions by capturing an image of an arc shape of an outer periphery of the target object when a support arm of the transfer unit is positioned at a predetermined position close to an inlet of the processing unit while supporting the target object; a calculation unit for calculating information on positional displacement of the target object with respect to the transfer unit by obtaining a phantom circle of the target object from the positional data on multiple positions of the arc shape of the target object and calculating center coordinates of the phantom circle; and a controller for receiving the information on positional displacement calculated by the calculation unit and controlling the transfer unit to correct the position of the target object so that the target object is loaded to a predetermined position in the processing unit.

In the first aspect of the present invention, two processing units may be disposed neighboring each other, and the image pickup device may be provided at a position neighboring both of the two processing units, and the image pickup device may capture an image of the arc shape of the outer periphery of the target object when the support arm of the transfer unit is positioned at a predetermined position close to an inlet of one processing unit while supporting the target object, and also capture an image of the arc shape of the outer periphery of the target object when the support arm of the transfer unit is positioned at a predetermined position close to an inlet of the other neighboring processing unit while supporting the target object.

Further, three or more processing units may be disposed neighboring one another, and the image pickup device may be provided at a position neighboring the three or more processing units, and the image pickup device may capture an image of the arc shape of the outer periphery of the target object when the support arm of the transfer unit is positioned at a predetermined position close to an inlet of one processing unit while supporting the target object, capture an image of the arc shape of the outer periphery of the target object when the support arm of the transfer unit is positioned at a predetermined position close to an inlet of another neighboring processing unit while supporting the target object, and capture an image of the arc shape of the outer periphery of the target object when the support arm of the transfer unit is positioned at a predetermined position close to an inlet of still another neighboring processing unit while supporting the target object.

Further, the process in which the image pickup device detects positional data on multiple locations by capturing the image of the arc shape of the outer periphery of the target object and the process in which the calculation unit calculates the central coordinates of the phantom circle of the target object based on the positional data on multiple positions may be set as a single sampling process, and the sampling process is performed multiple times.

Further, the image pickup device may capture an image of the support arm of the transfer unit, and the calculation unit may determine whether or not the target object is mounted on the support arm based on the captured image data. Further, the image pickup device may capture an image of the support arm of the transfer unit, and the calculation unit may calculate calibration data of the support arm.

Further, the presence or non-presence of the target object may be determined based on the image captured by the image pickup device.

In this case, when an edge of the target object is not recognized by the image pickup device, the controller may first detect the presence or non-presence of the target object by using the image pickup device, detect a displacement direction of the target object based on the detection result, drive the support arm based on the displacement direction of the target object to position the edge of the target object within a detection range of the image pickup device, and obtain a position of the target object by capturing an image of an arc shape corresponding to the edge.

Next, the controller may drive the support arm to position a portion of the target object, that is symmetrical to the detected portion of the target object, within the detection range of the image pickup device, obtain a position of the target object by capturing an image of an arc shape corresponding to the edge of the target object, which corresponds to the symmetrical portion, by the image pickup device, compare the two positions of the target object, and recognize the obtained position of the target object as a position of the target object when both positions coincide with each other within an allowable range of error.

Further, when an edge of the target object is recognized by the image pickup device at a position where a measurement accuracy is not assured, the controller may first obtain a position of the target object by capturing an image of an arc shape corresponding to the edge of the target object by the image pickup device, next, drive the support arm to position the edge of the target object within an area where the measurement accuracy is assured, obtain a position of the target object again by capturing an image of an arc shape corresponding to the edge of the target object by the image pickup device, compare the two positions of the target object, and recognize the newly obtained position of the target object as a position of the target object when both coincide with each other within an allowable range of error.

In accordance with a second aspect of the present invention, there is provided a processing method of a processing apparatus including at least one processing unit, a transfer unit having a transfer unit for loading and unloading a circular target object to be processed into and from the processing unit, and an image pickup device for capturing an image of an arc shape of an outer periphery of the target object, the method including: detecting positional data on multiple positions by capturing an image of the arc shape of the outer periphery of the target object by the image pickup device when a support arm of the transfer unit is positioned at a predetermined position close to an inlet of the processing unit while supporting the target object; calculating information on positional displacement of the target object with respect to the transfer unit by obtaining a phantom circle of the target object from the positional data on multiple positions of the arc shape of the target object and calculating central coordinates of the phantom circle; and controlling the transfer unit based on the information on positional displacement to correct the position of the target object so that the target object is loaded to a predetermined position in the processing unit.

In the second aspect of the present invention, two processing units may be disposed neighboring each other, and the image pickup device may be provided at a position neighboring both of the two processing units, and the method may include: capturing an image of the arc shape of the outer periphery of the target object by the image pickup device when the support arm of the transfer unit is positioned at a predetermined position close to an inlet of one processing unit while supporting the target object, and capturing an image of the arc shape of the outer periphery of the target object by the image pickup device when the support arm of the transfer unit is positioned at a predetermined position close to an inlet of the other neighboring processing unit while supporting the target object.

Further, three or more processing units may be disposed neighboring one another, and the image pickup device may be provided at a position neighboring the three or more processing units, and the method may include: capturing an image of the arc shape of the outer periphery of the target object by the image pickup device when the support arm of the transfer unit is positioned at a predetermined position close to an inlet of one processing unit while supporting the target object, capturing an image of the arc shape of the outer periphery of the target object by the image pickup device when the support arm of the transfer unit is positioned at a predetermined position close to an inlet of another neighboring processing unit while supporting the target object, and capturing an image of the arc shape of the outer periphery of the target object by the image pickup device when the support arm of the transfer unit is positioned at a predetermined position close to an inlet of still another neighboring processing unit while supporting the target object.

Further, said detecting positional data on multiple positions by capturing the image of the arc shape of the outer periphery of the target object and said calculating the central coordinates of the phantom circle of the target object may be set as a single sampling process, and the sampling process is performed multiple times.

The processing method may further includes capturing an image of the support arm of the transfer unit by the image pickup device; and determining whether or not the target object is mounted on the support arm based on the captured image data. Further, the processing method may also include capturing an image of the support arm of the transfer unit of the target object by the image pickup device; and calculating calibration data of the support arm.

In accordance with a third aspect of the present invention, there is provided a method of recognizing a circular target object to be processed in a processing apparatus including at least one processing unit, a transfer chamber having a transfer unit for loading and unloading the target object into and from the processing unit, and an image pickup device for capturing an image of an edge of the target object when a support arm of the transfer unit is positioned at a predetermined position close to an inlet of the processing unit while supporting the target object, wherein when the edge of the target object is not recognized by the image pickup device in a state where the support arm of the transfer unit which supports the target object is positioned at a predetermined position in the processing unit.

The method of recognizing the target object may includes: detecting the presence or non-presence of the target object by the image pickup device, recognizing a displacement direction of the target object based on the detection result, and driving the support arm based on the displacement direction; positioning the edge of the target object within a detection range of the image pickup device and obtaining a position of the target object by capturing an image of an arc shape corresponding to the edge of the target object by the image pickup device; driving the support arm to position a portion of the target object, that is symmetrical to the detected portion of the target object, within the detection range of the image pickup device and obtaining a position of the target object by capturing an image of an arc shape corresponding to the edge, which corresponds to the symmetrical portion, by the image pickup device; comparing the two positions of the target object; and recognizing the newly obtained position of the target object as a position of the target object when both positions coincide with each other within an allowable range of error.

In accordance with a fourth aspect of the present invention, there is provided a method of recognizing a circular target object in a processing apparatus including at least one processing unit, a transfer chamber having a transfer unit for loading and unloading the target object into and from the processing unit, and an image pickup device for capturing an image of an edge of the target object when a support arm of the transfer unit is positioned at a predetermined position close to an inlet of the processing unit while supporting the target object, wherein when the edge of the target object is recognized by the image pickup device at a position where measurement accuracy is not assured in a state where the support arm of the transfer unit which supports the target object is positioned at a predetermined position in the processing unit.

The method of recognizing the target object may include: obtaining a position of the target object by capturing an image of an arc shape corresponding to the edge of the target object by the image pickup device; driving the support arm to position the edge of the target object within an area where the measurement accuracy is assured; obtaining a position of the target object again by capturing an image of an arc shape corresponding to the edge of the target object by the image pickup device; comparing the two positions of the target object; and recognizing the newly obtained position as a position of the target object when both positions coincide with each other within an allowable range of error.

In accordance with a fifth aspect of the present invention, there is provided a computer operable storage medium storing a program for controlling a processing apparatus including at least one processing unit, a transfer chamber having a transfer unit for loading and unloading a circular target object to be processed into and from the processing unit, and an image pickup device for capturing an image of an edge of the target object.

Herein, the program, when executed on a computer, controls processing apparatus to perform a processing method including: detecting positional data on multiple positions by capturing an image of the arc shape of the outer periphery of the target object by the image pickup device when a support arm of the transfer unit is positioned at a predetermined position close to an inlet of the processing unit while supporting the target object; calculating information on positional displacement of the target object with respect to the transfer unit by obtaining a phantom circle of the target object from the positional data on multiple positions of the arc shape of the target object and calculating central coordinates of the phantom circle; and controlling the transfer unit based on the information on positional displacement to correct the position of the target object so that the target object is loaded to a predetermined position in the processing unit.

In accordance with a sixth aspect of the present invention, there is provided a computer operable storage medium storing a program for controlling a processing apparatus including at least one processing unit, a transfer chamber having a transfer unit for loading and unloading a circular target object to be processed into and from the processing unit, and an image pickup device for capturing an image of an edge of the target object when a support arm of the transfer unit is positioned at a predetermined position close to an inlet of the processing unit while supporting the target object, wherein the program, when executed on a computer, controls the processing apparatus to perform a method of recognizing the target object.

Herein, when the edge of the target object is not recognized by the image pickup device in a state where the support arm of the transfer unit which supports the target object is positioned at a predetermined position in the processing unit, the method of recognizing the target object includes: detecting the presence or non-presence of the target object by the image pickup device, recognizing a displacement direction of the target object based on the detection result, and driving the support arm based on the displacement direction; positioning the edge of the target object within a detection range of the image pickup device and obtaining a position of the target object by capturing an image of the arc shape corresponding to the edge of the target object by the image pickup device; driving the support arm to position a portion of the target object, that is symmetrical to the detected portion of the target object, within the detection range of the image pickup device and obtaining a position of the target object by capturing an image of the arc shape corresponding to the edge, which corresponds to the symmetrical portion, by the image pickup device; comparing the two positions of the target object; and recognizing the newly obtained position of the target object as a position of the target object when both positions coincide with each other within an allowable range of error.

In accordance with a seventh aspect of the present invention, there is provided a computer operable storage medium storing a program for controlling a processing apparatus including at least one processing unit, a transfer chamber having a transfer unit for loading and unloading a circular target object to be processed into and from the processing unit, and an image pickup device for capturing an image of an edge of the target object when a support arm of the transfer unit is positioned close to an inlet of the processing unit while supporting the target object, wherein the program, when executed on a computer, controls the processing apparatus to perform a method of recognizing the target object.

Herein, when the edge of the target object is recognized by the image pickup device at a position where measurement accuracy is not assured in a state where the support arm of the transfer unit which supports the target object is positioned at a predetermined position in the processing unit, the method of recognizing the target object includes: obtaining a position of the target object by capturing an image of an arc shape corresponding to the edge of the target object by the image pickup device; driving the support arm so as to position the edge of the target object within an area where the measurement accuracy is assured; obtaining a position of the target object again by capturing an image of an arc shape corresponding to the edge of the target object by the image pickup device; comparing the two positions of the target object; and recognizing the newly obtained position of the target object as a position of the target object when both positions coincide with each other within an allowable range of error.

In accordance with the present invention, and the information on positional displacement of a target object with respect to the transfer unit is obtained by capturing an image of an arc shape of an outer periphery of a target object by an image pickup device. Thus, the information on positional displacement can be detected with high accuracy.

Further, the positional data can be detected by capturing the image of the arc shape of the outer periphery of the target object by a single image pickup device. Accordingly, it is possible to reduce the number of detectors compared to the case of using a laser displacement sensor, and also possible to shorten the adjustment time. Moreover, even when the target object is not normally recognized by the image pickup device due to the large displacement thereof, the processing can be continued without stopping the apparatus. Therefore, the deterioration of the productivity can be suppressed.

### BRIEF DESCRIPTION OF THE DRAWINGS

FIG. 1 explains transfer of a semiconductor wafer in a transfer chamber to a processing unit.

FIG. 2 explains transfer of a semiconductor substrate in a transfer chamber to a processing unit after correcting the position thereof.

FIG. 3 provides a horizontal cross sectional view of a schematic structure of a multi-chamber type processing apparatus in accordance with an embodiment of the present invention.

FIG. 4 shows a bottom view of a transfer chamber shown in FIG. 3.

FIG. 5 illustrates a side cross sectional view of the transfer chamber shown in FIG. 3 and a position correction control unit.

FIG. 6 presents a top view of the transfer chamber shown in FIG. 3.

FIG. 7 represents a schematic view for explaining an image pickup range of a CCD of an image pickup device.

FIG. 8 depicts a flow chart of a process of detecting “information on positional displacement” of a semiconductor wafer with respect to a blade (support arm) of a transfer unit.

FIG. 9 describes a flow chart of a process of recognizing the semiconductor wafer in a case where an edge of the semiconductor wafer cannot be recognized.

FIG. 10A is a schematic view of exemplary displacement of the semiconductor wafer in a case where the edge of the semiconductor wafer cannot be recognized.

FIG. 10B is a schematic view of another exemplary displacement of the semiconductor wafer in a case where the edge of the semiconductor wafer cannot be recognized.

FIG. 11 is a schematic view showing a state where a position of a support arm is corrected so that the edge of the semiconductor wafer is positioned within a detection range.

FIG. 12 is a schematic view showing a state where the support arm is moved so that a site symmetrical to the detection site of the semiconductor wafer is positioned within a detection range of a CCD detector.

FIG. 13 provides a flow chart of a process of recognizing a semiconductor wafer in a case where a displacement amount of the semiconductor wafer is larger than an allowable amount in the characteristics of the CCD detector.

FIG. 14 presents a schematic view explaining a case where a displacement amount of the semiconductor wafer is larger than an allowable amount in the characteristics of the CCD detector.

FIG. 15 offers a schematic view showing a state where the position of the support arm is corrected so that the edge of the semiconductor wafer is positioned within an area in the detection range where measurement accuracy can be assured.

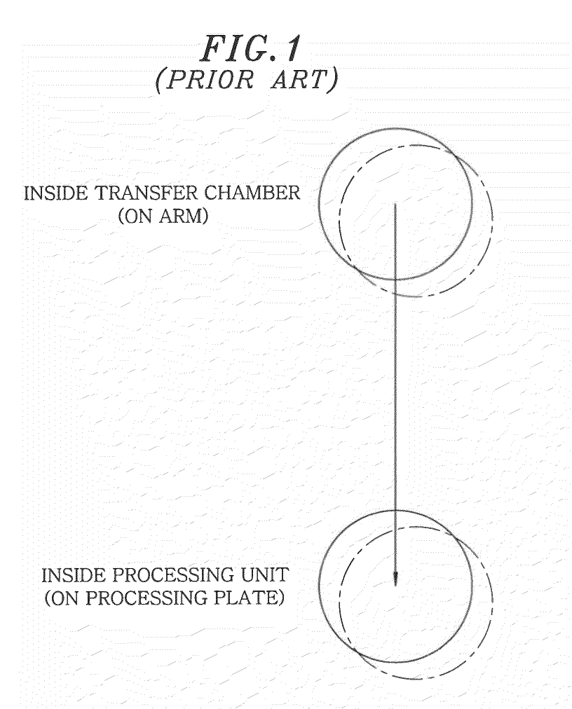

### DETAILED DESCRIPTION OF EMBODIMENTS

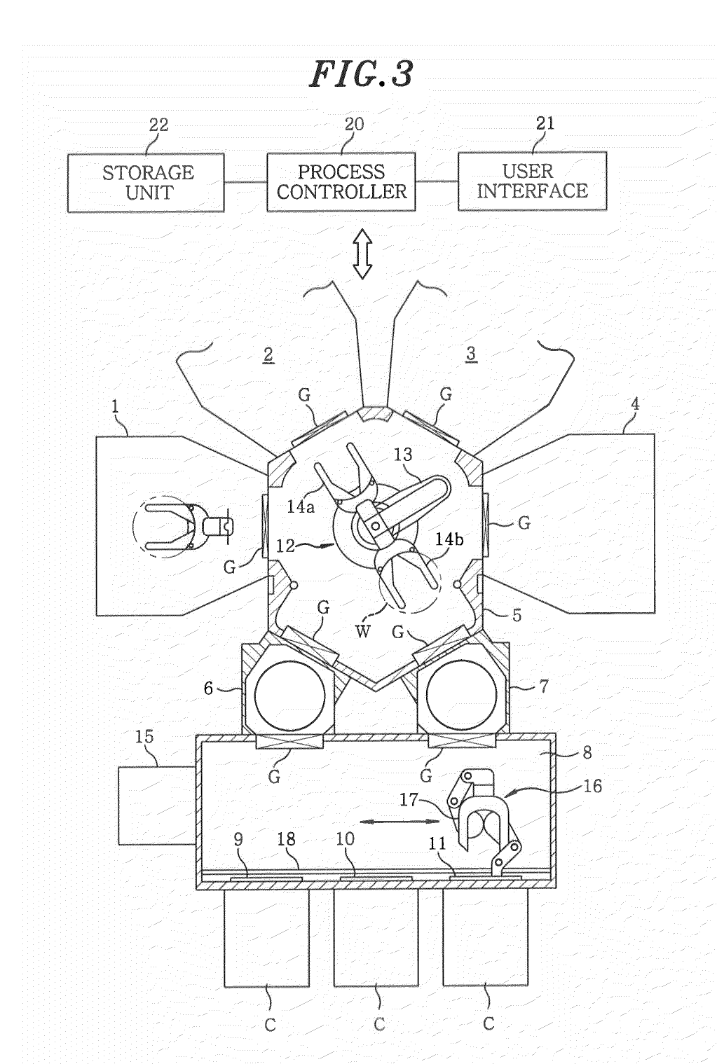

Hereinafter, embodiments of the present invention will be described in detail with reference to the accompanying drawings. FIG. 3 is a horizontal cross sectional view showing a schematic structure of a multi-chamber type processing apparatus in accordance with an embodiment of the present invention.

The processing apparatus includes four processing units 1 to 4, and the processing units 1 to 4 are provided in a corresponding relationship with four sides of a hexagonal transfer chamber 5. Further, load-lock chambers 6 and 7 are provided on the remaining two sides of the transfer chamber 5, and a loading/unloading chamber 8 is provided on the other sides of the load-lock chambers 6 and 7 opposing the sides thereof to which the transfer chamber 5 is connected. Ports 9 to 11 to which three carriers C capable of accommodating therein semiconductor wafers W as substrates to be processed are attached are provided on a side of the loading/unloading chamber 8 opposing the sides thereof to which the load-lock chambers 6 and 7 are connected. Each of the processing units 1 to 4 performs a predetermined vacuum processing, e.g., etching or film-forming, on a target object to be processed mounted on a corresponding processing plate.

The processing units 1 to 4 and the load-lock chambers 6 and 7 are connected to the respective sides of the transfer chamber 5 through gate valves G as shown in FIG. 3. Each of the processing units 1 to 4 and the load-lock chambers 6 and 7 communicates with the transfer chamber 5 by opening a corresponding gate valve G, and is disconnected from the transfer chamber 5 by closing the corresponding gate valve G. Moreover, the load-lock chambers 6 and 7 are connected to the loading/unloading chamber 8 through gate valves G. Each of the load-lock chambers 6 and 7 communicates with the loading/unloading chamber 8 by opening a corresponding gate valve G, and is disconnected from the loading/unloading chamber 8 by closing the gate valve G.

Installed in the transfer chamber 5 is a transfer unit 12 for loading and unloading the semiconductor wafer W into and from the processing units 1 to 4 and the load-lock chambers 6 and 7. The transfer unit 12 includes a rotatable and extensible/contractible portion 13 arranged substantially at the center of the transfer chamber 5 and two support arms 14a and 14b for supporting the semiconductor wafer W, the support arms 14a and 14b being attached to the leading end of the rotatable and extensible/contractible portion 13 while being oriented in opposite directions. Further, the inside of the transfer chamber 5 is maintained at a predetermined vacuum level. Although the twin type support arms 14a and 14b are employed in this example, a single type support arm may be used.

Shutters (not shown) are installed in the ports 9 to 11 of the loading/unloading chamber 8 to which the carriers are attached. When the carriers C, either accommodating semiconductor wafers W therein or remaining empty, are directly attached to the ports 9 to 11, the shutters are open so that the carriers C are allowed to communicate with the loading/unloading chamber 8 while preventing infiltration of external air. Further, provided at a lateral side of the loading/unloading chamber 8 is an alignment chamber 15 in which alignment of the semiconductor wafer W is carried out.

Disposed in the loading/unloading chamber 8 is a transfer unit 16 for loading and unloading the semiconductor wafer W into and from the carrier C and the load-lock chambers 6 and 7. The transfer unit 16 has a multi-joint arm structure and can move along a rail 18 arranged parallel to the carriers C. The transfer unit 16 carries out the transfer of the semiconductor wafer W while holding the semiconductor wafer W on a hand 17 provided at a leading end thereof.

The processing apparatus includes a process controller 20 having a micro processor (computer) for controlling each of the units, and each of the units are connected to and controlled by the process controller 20. Further, the process controller 20 is connected to a user interface 21 including a keyboard through which an operator performs a command input or other operations to manage the processing apparatus, a display for visually displaying the operating conditions of the plasma processing apparatus, and so forth.

Further, the process controller 20 is connected to a storage unit 22 which stores therein control programs to be used in realizing various processes performed by the processing apparatus under the control of the process controller 20 and programs, i.e., recipes, to be used in operating the respective components of the processing units to carry out processes under controlled processing conditions. The processing recipes are stored in a storage medium provided inside the storage unit 22. The storage medium may be a hard disk, a semiconductor memory or a portable memory such as a CD-ROM, a DVD, and a flash memory. Alternatively, the recipes may be suitably transmitted from other devices via, e.g., a dedicated transmission line.

If necessary, an arbitrary one of the recipes is read out from the storage unit 22 under the instruction inputted through the user interface 21 and is executed by the process controller 20. Thus, the processing units perform a desired processing under the control of the process controller 20.

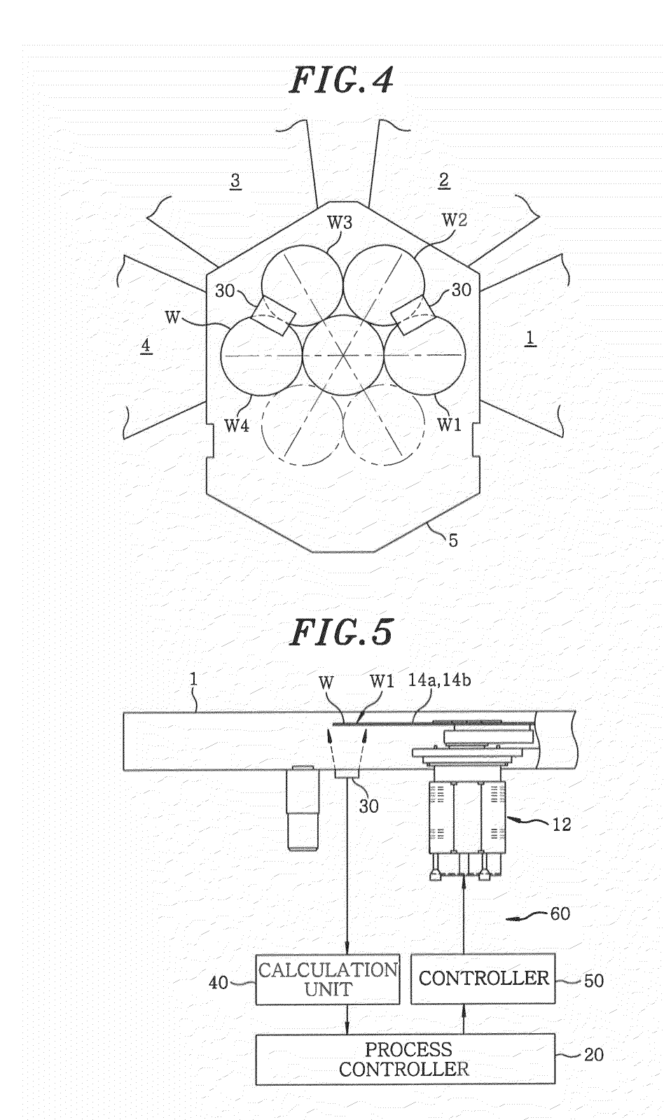

FIG. 4 shows a bottom view of the transfer chamber shown in FIG. 3. In order to load the semiconductor wafer W into one of the processing units by using the support arm 14a or 14b of the transfer unit 12, the semiconductor wafer W supported by the support arm 14a or 14b is positioned at a predetermined position in the transfer chamber 5 close to the inlet of the corresponding one of the processing units 1 to 4, i.e., at one of standby positions indicated as W1 to W4 in FIG. 4 and, then, the support arm 14a or 14b is loaded into the corresponding processing unit. Further, two CCD detectors (CCD cameras) 30 serving as image pickup devices are positioned close to the standby positions W1 to W4 on the bottom wall of the transfer chamber 5. Accordingly, an image of the semiconductor wafer W that is positioned at one of the standby positions W1 to W4 can be captured, and “information on positional displacement” of the semiconductor wafer W with respect to a predetermined position can be detected. Moreover, the presence or non-presence of the semiconductor wafer W can be detected by each of the CCD detectors 30.

One of the CCD detectors 30 can capture an image of an arc shape of an outer periphery of a semiconductor wafer W positioned at a standby position W1 close to the inlet of the processing unit 1 and also that at a standby position W2 close to the inlet of the neighboring processing unit 2. The other CCD detector 30 can capture an image of an arc shape of an outer periphery of a semiconductor wafer W positioned at a standby position W3 close to the inlet of the processing unit 3 and also that at a standby position W4 close to the neighboring inlet of the processing unit 4.

FIG. 5 illustrates a side cross sectional view of a transfer chamber shown in FIG. 3 and a position correction control unit. A position correction control unit 60 includes: a calculation unit 40 for calculating the information on positional displacement and position information of the semiconductor wafer W at the standby position from the captured data of the arc shape of the outer periphery of the semiconductor wafer W which is obtained by the CCD detector 30; and a controller 50 for controlling the transfer unit 12 based on the information on positional displacement that is calculated by the calculation unit 40.

In the calculation unit 40, the image data of the arc shape of the outer periphery of the semiconductor wafer W captured by the CCD detector 30 is received; the positional data on multiple positions of the arc shape of the outer periphery of the semiconductor wafer W are detected from the captured image data; a phantom circle of the semiconductor wafer W is obtained; and central coordinates thereof are calculated. Moreover, “information on positional displacement” of the semiconductor wafer W is calculated based on central coordinates of the semiconductor wafer W at the standby position and the calculated central coordinates.

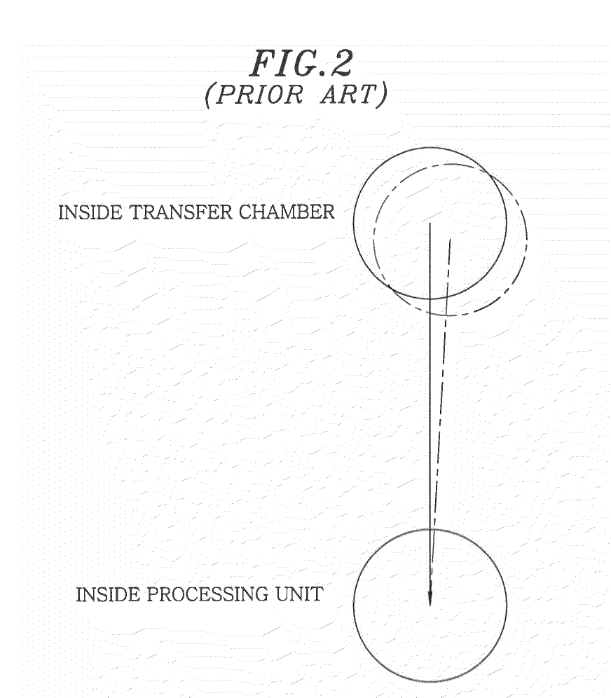

The “information on positional displacement” of the semiconductor wafer W is sent from the calculation unit 40 to the process controller 20. Next, the information is sent to the controller 50 of the transfer unit 12 at a predetermined timing. The controller 50 outputs control information to the transfer unit 12 to control the transfer unit 12 based on the information on positional displacement. In other words, the controller 50 performs a feedback control on the transfer unit 12 to transfer the semiconductor wafer W to a predetermined position in the processing unit based on the “information on positional displacement.” Accordingly, the semiconductor wafer W whose positional displacement is corrected is transferred onto a predetermined processing plate, as can be seen from FIG. 2.

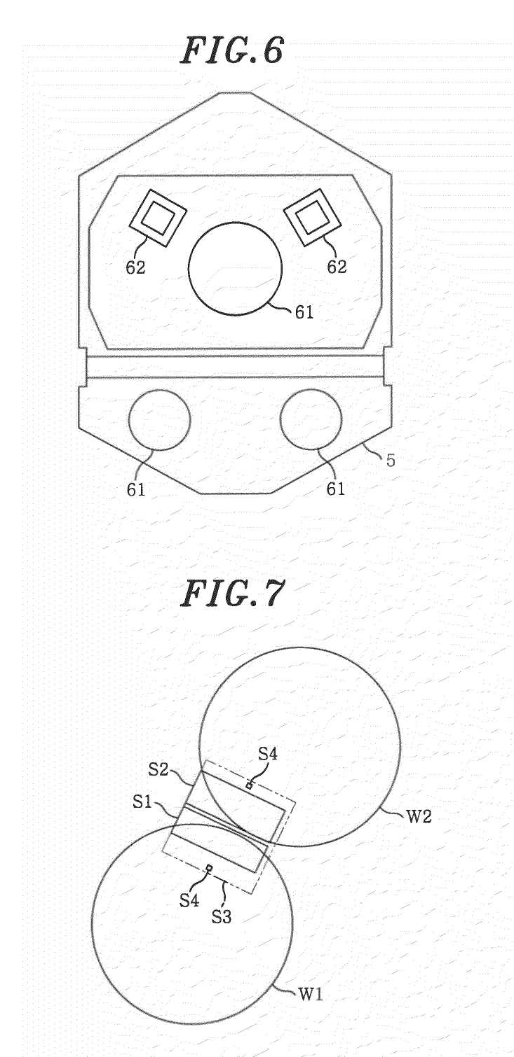

FIG. 6 is a top view of the transfer chamber shown in FIG. 3. Provided on a ceiling plate of the transfer chamber 5 are a plurality of observation windows for observing the inside of the transfer chamber 5 and covers 61 for covering the observation windows to prevent external disturbance light. In addition, a plurality of LEDs 62 is provided as lighting sources for the CCD detectors 30.

FIG. 7 is a schematic view showing image pickup range of the CCD detector serving as the image pickup device. The CCD detector 30 of the processing units 1 and 2 have a first sight S1 for capturing an image of an arc shape of an outer periphery of a semiconductor wafer W positioned at the standby position W1 to be loaded into the processing unit 1 and a second sight S2 for capturing an image of an arc shape of an outer periphery of a semiconductor wafer W positioned at the standby position W2 to be loaded into the processing unit 2. Besides, a rectangle S3 indicated by a phantom line represents an area that can be captured by a single CCD detector 30. Further, small rectangles S4 indicate ON/OFF determination areas of 0.5×0.5 mm square.

For example, from the first sight S1, the image of the arc shape of the outer periphery of the semiconductor wafer W at the standby position W1 is picked up, thereby detecting positional data on multiple positions in the arc shape of the outer periphery of the semiconductor wafer W. The number of multiple positions where the positional data are detected is, e.g., 100.

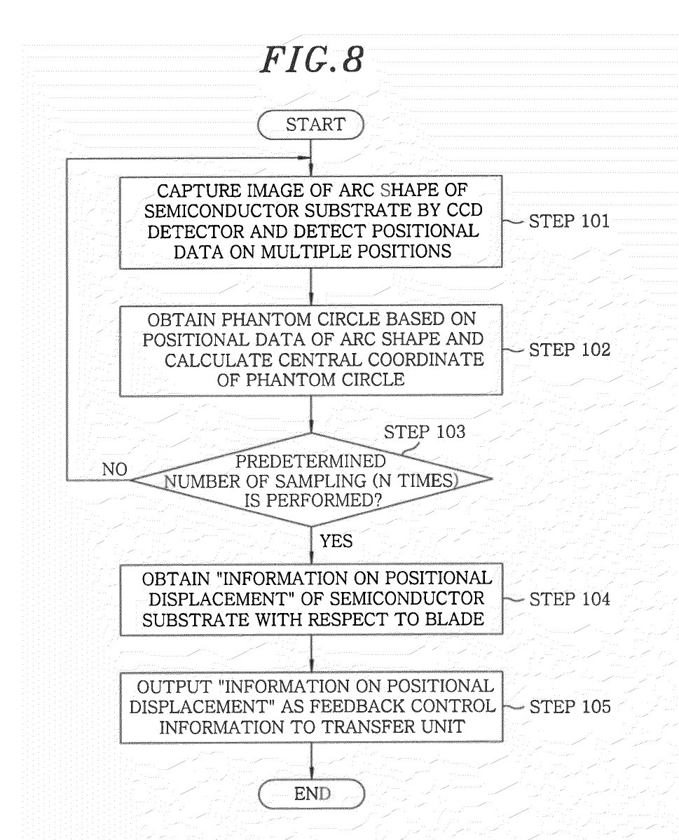

Hereinafter, a series of processes for correcting position displacement by detecting the “information on positional displacement” when the semiconductor wafer is transferred into the processing unit will be described. FIG. 8 provides a flow chart of a process for correcting positional displacement by detecting the “information on positional displacement” when the semiconductor wafer is transferred into the processing unit.

First of all, as described above, an image of an arc shape of an outer periphery of a semiconductor wafer W positioned at a standby position close to an inlet of one of the processing units 1 to 4 is captured, and positional data on multiple positions in the arc shape of the outer periphery of the semiconductor wafer W are detected (step 101).

Next, a phantom circle of the semiconductor wafer W is obtained based on the positional data obtained on multiple positions in the arc shape of the outer periphery of the semiconductor wafer W, and central coordinates of the phantom circle in a two-dimensional coordinate system are calculated (step 102).

The steps 101 and 102 are set as a single sampling process, and the sampling process is performed a predetermined number of times (N times) (step 103). The calculated central coordinates of the phantom circle of the semiconductor wafer W are averaged by the predetermined number of times (N times) of performing the sampling process.

Here, in order to increase the accuracy of the “information on positional displacement” of the semiconductor wafer W with respect to the support arm 14a or 14b, it is preferable to increase the number of times (N times) of performing the sampling process. However, if the number of times of performing the sampling process increases, the processing time during which the semiconductor wafer W is on standby at one of the standby positions W1 to W4 close to the inlets of the processing units 1 to 4 increases, which is not preferable. That is, the improvement in the accuracy of the “information on positional displacement” that can be realized by increasing the number of times (N times) of performing the sampling process has a trade-off relationship with the processing time.

Thus, there is a need to optimize by balancing the accuracy of the “information on positional displacement” and the processing time. To be specific, while considering the accuracy of the “information on positional displacement” required for each of the processing apparatuses, the number of times (N times) of performing the sampling process is controlled such that there will be allowed appropriate time for the processing time such as an exchanging time or a standby time of the semiconductor wafer W.

Next, the “information on positional displacement” of the semiconductor wafer W at the standby position is obtained from the calculated central coordinates of the phantom circle of the semiconductor wafer W (step 104). In other words, the “information on positional displacement” of the semiconductor wafer W is calculated based on the predetermined central coordinates of the semiconductor wafer W at the standby position and the central coordinates of the phantom circle.

Thereafter, the feedback control information is outputted from the controller 50 to the transfer unit 12 based on the calculated “information on positional displacement.” The transfer unit 12 is feedback-controlled to transfer the semiconductor wafer W to a predetermined position of the processing unit (step 105).

Accordingly, the semiconductor wafer W whose positional displacement is corrected can be transferred onto a predetermined processing plate in each of the processing units 1 to 4, as illustrated in FIG. 2. As a result, the processing can be performed while the positional displacement of the semiconductor wafer W is being minimized.

As described above, in accordance with the present embodiment, the CCD detector 30 directly captures the image of the arc shape of the outer periphery of the semiconductor wafer W held on the transfer unit to thereby obtain the “information on positional displacement” of the target object, so that the “information on positional displacement” can be detected with remarkably high accuracy. Therefore, the positional displacement of the semiconductor wafer W on the processing plate in the processing unit can be remarkably minimized by controlling the transfer unit 12 based on the “information on positional displacement” and correcting the position of the semiconductor wafer W.

In addition, the positional data can be detected by capturing the image of the arc shape of the outer periphery of the semiconductor wafer W by a single CCD detector 30, so that it is possible to remarkably reduce the adjustment time and the number of detectors compared to the case of using a laser displacement sensor.

Further, the positional data on multiple positions can be detected by capturing the image of the arc shape of the outer periphery of the semiconductor wafer W positioned at each of the standby positions close to the inlets of two neighboring processing units among the processing units 1 to 4. Accordingly, the number of detectors and the adjustment time thereof can be further reduced.

As describe above, the central position of the semiconductor wafer W and the positional displacement of the semiconductor wafer W can be detected with high accuracy in accordance with the present embodiment. However, in this embodiment, the presence or non-presence of the wafer and the position of the wafer are both detected by capturing the edge of the semiconductor wafer W by the CCD detector 30, so that the margin of the measurable positional displacement is very small. In other words, in the present embodiment, the edge of the semiconductor wafer W needs to be within the detection range (sight) of the CCD detector 30. When the semiconductor wafer W is not positioned inside the detection range, it can be recognized as the “no wafer”. On the other hand, if the semiconductor wafer W is positioned such that the detection range is inside the semiconductor wafer W, the detection error will occur. Since the detection range of each CCD detector 30 is narrow, the measurable margin is small. Therefore, the edge of the semiconductor wafer W is often displaced away from the sight of the CCD detector 30. Moreover, even when the edge of the semiconductor wafer W is within the sight of the CCD detector 30, the measurement accuracy cannot be assured if the displacement amount of the wafer is larger than the allowable amount. In that case as well, the detection error occurs.

Whenever the “no wafer” is recognized or the detection error occurs, the apparatus is stopped, thereby decreasing the productivity considerably.

Thus, in the above cases, the positional displacement of the semiconductor wafer W is measured again in a following sequence.

(Case 1: in Case where an Edge of a Semiconductor Wafer is not Recognized)

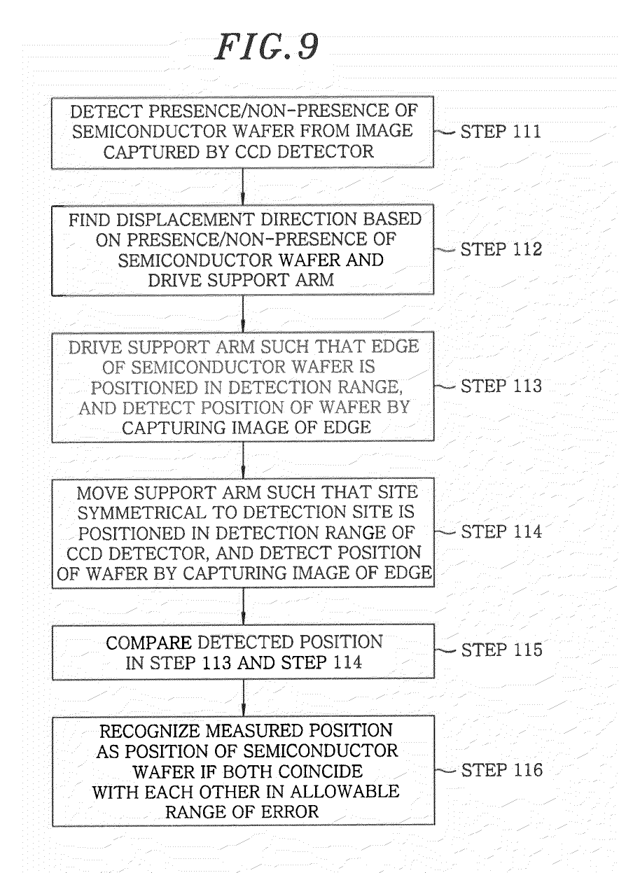

The edge of the semiconductor wafer cannot be recognized, if the displacement amount of the semiconductor wafer is large. In this case, the position of the wafer can be recognized by securing two or more measurement points. For example, the processes shown in the flow chart of FIG. 9 are carried out. First, the presence or non-presence of the semiconductor wafer is detected from the image captured by the CCD detector 30 (step 111).

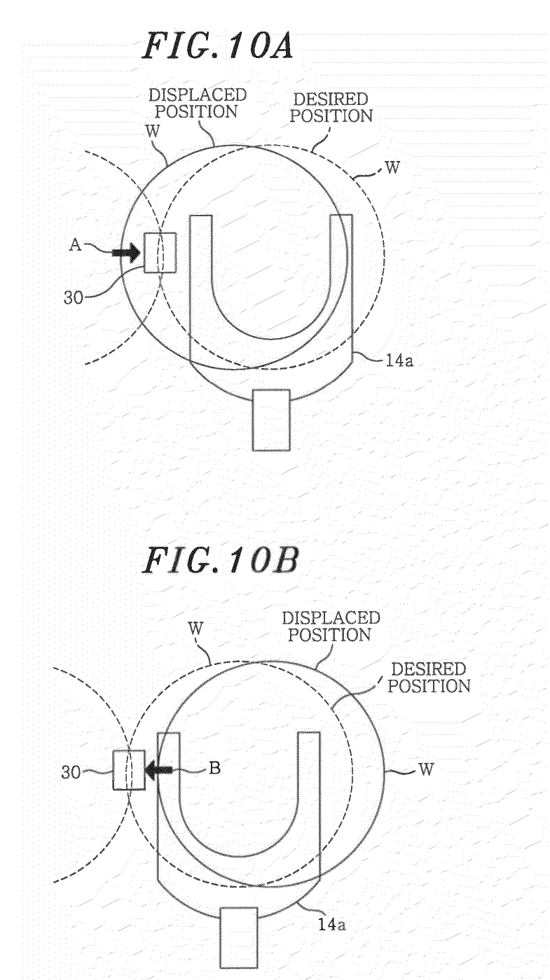

Next, the displacement direction of the semiconductor wafer is found out from the detection result, and the support arm 14a or 14b supporting the semiconductor wafer W is driven at a low speed to move the edge of the semiconductor wafer W (the edge being the boundary where the presence/non-presence of the semiconductor wafer W being decided) toward the measurement range of the CCD detector 30 (step 112). In other words, when the semiconductor wafer is present, the semiconductor wafer W is displaced on the support arm 14a (or 14b) as shown in FIG. 10A and, therefore, the semiconductor wafer W is moved by the support arm 14a (or 14b) to a direction indicated by an arrow A. On the other hand, when no semiconductor wafer is detected, the semiconductor wafer W is displaced as shown in FIG. 10B and, hence, the semiconductor wafer W is moved by the support arm 14a (or 14b) to a direction indicated by an arrow B.

Further, as depicted in FIG. 11, the support arm 14a (or 14b) is driven to correct the edge of the semiconductor wafer W to be positioned within the detection range, and the position of the semiconductor wafer W on the support arm 14a (or 14b) is detected by capturing the image of the arc shaped edge in the above-described sequence (step 113).

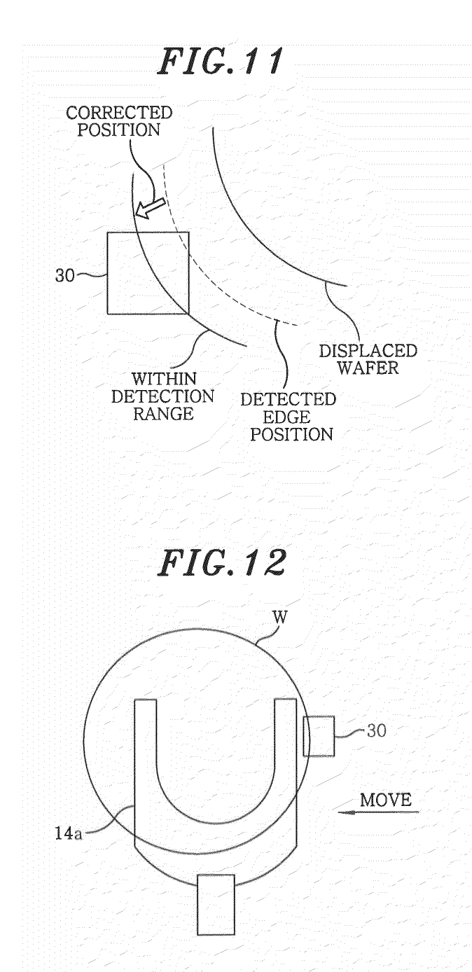

Next, as shown in FIG. 12, the support arm 14a (or 14b) is moved so that a site symmetrical to the detection site of the semiconductor wafer W is positioned within the detection range of the CCD detector 30, and the position of the semiconductor wafer W on the support arm 14a (or 14b) is detected by capturing the image of the arc shaped edge in the above-described sequence (step 114).

Thereafter, the position of the semiconductor wafer W that is detected in the step 113 is compared with the position of the semiconductor wafer W that is detected in the step 114 (step 115). When both coincide with each other within an allowable range of error, the measured position of the semiconductor wafer W with respect to the support arm 14a (or 14b) is recognized as the position of the semiconductor wafer W (step 116).

(Case 2: in Case where a Displacement Amount of a Semiconductor Wafer is Larger than an Allowable Amount in the Characteristics of the CCD Detector 30)

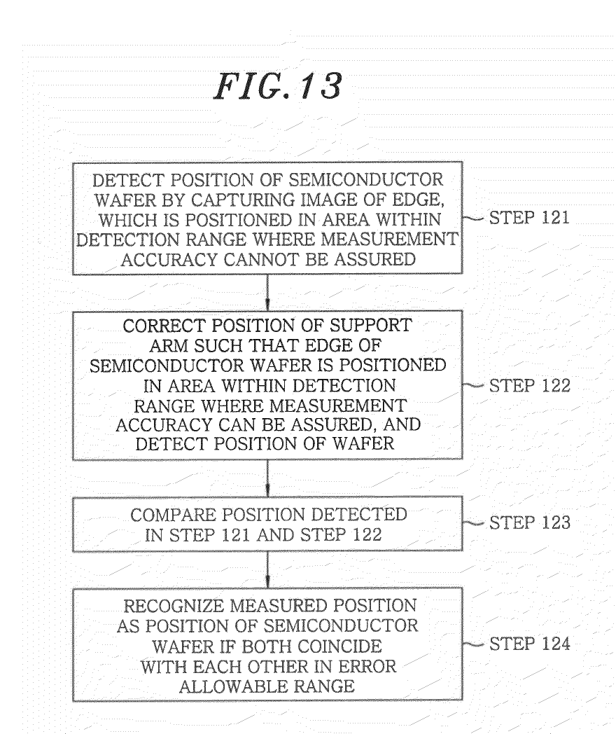

In that case, the measurement accuracy is assured by moving the semiconductor wafer W to the position at which the displacement amount of the semiconductor wafer W can be accurately measured. For example, the processes shown in the flow chart of FIG. 13 are carried out.

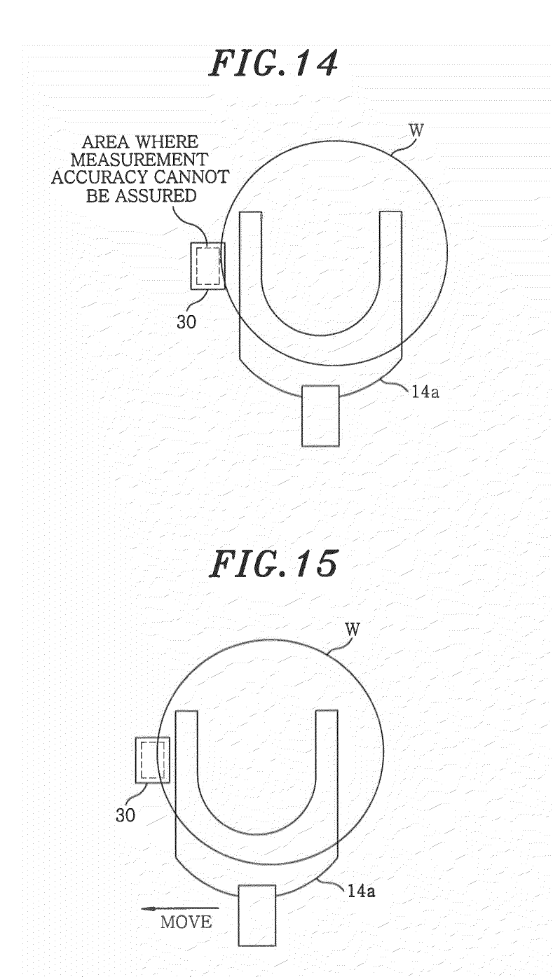

If the displacement amount of the semiconductor wafer W is larger than the allowable amount in the characteristics of the CCD detector 30, the measurement accuracy cannot be assured even though the edge of the semiconductor wafer W is positioned within the detection range as shown in FIG. 14. Thus, the position of the semiconductor wafer W on the support arm 14a (or 14b) is detected by capturing the image of the arc shaped edge of the semiconductor wafer W in that position by the CCD detector 30 in the above-described sequence (step 121).

Next, as illustrated in FIG. 15, the position of the support arm 14a (or 14b) is driven to correct the edge of the semiconductor wafer W to be positioned in the area within the detection range where the measurement accuracy can be assured (step 122). Thereafter, the position of the semiconductor wafer W on the support arm 14a (or 14b) is detected as in the above-described sequence.

Then, the position of the semiconductor wafer W detected in step 121 is compared with the position of the semiconductor wafer W detected in the step 122 (step 123). When both coincide with each other within the allowable error range, the measured position is recognized as the position of the semiconductor wafer (step 124).

In this manner, even when the “no wafer” is detected or the detection error occurs due to the large displacement of the semiconductor wafer W, the transfer can be continued and, also, the processing can be continued without stopping the apparatus. In addition, even when a returning operation is required by an auxiliary operation of an operator, the position of the wafer can be recognized accurately and, thus, a returning time from a transfer error state can be reduced considerably.

The present invention can be variously modified without being limited to the above-described embodiments.

For example, in the above embodiment, a CCD detector serving as an image pickup device is positioned close to two neighboring processing units, and the arc shape of the semiconductor wafer is detected at each of the standby positions corresponding to the two processing units. However, the CCD detector serving as the image pickup device can be provided close to three or more neighboring processing units, and the arc shape of the semiconductor wafer can be detected at each of the standby positions corresponding to the three or more processing units.

Moreover, a portion corresponding to a support arm of a transfer unit may be captured by the CCD detector serving as the image pickup device so that it is possible to check whether or not the semiconductor wafer is mounted on the support arm based on the image data thus obtained. As a consequence, the presence or non-presence of the semiconductor wafer as well as the positional information on the semiconductor wafer can be detected.

Further, the calibration data of the support arm can be calculated by capturing the image of the support arm of the transfer unit by the CCD detector serving as the image pickup device. Accordingly, the “positional displacement” can be treated only due to the semiconductor wafer.

Moreover, although the CCD detector is used as image pickup device in the above-described embodiment, other image pickup device such as CMOS detector and the like may be used without being limited to the above example. Further, although the semiconductor wafer W is used as a target object to be processed in the above-described embodiments, it is not limited to the above example.

What is claimed is:

1. A processing apparatus comprising:
at least one processing unit;
a transfer chamber including a transfer unit for loading and unloading a circular target object to be processed into and from the processing unit;
an image pickup device for detecting positional data on multiple positions by capturing an image of an arc shape of an outer periphery of the target object when a support arm of the transfer unit is positioned at a predetermined position close to an inlet of the processing unit while supporting the target object;
a calculation unit for calculating information on positional displacement of the target object with respect to the transfer unit by obtaining a phantom circle of the target object from the positional data on multiple positions of the arc shape of the target object and calculating center coordinates of the phantom circle; and
a controller for receiving the information on positional displacement calculated by the calculation unit and controlling the transfer unit to correct the position of the target object so that the target object is loaded to a predetermined position in the processing unit.

2. The processing apparatus of claim 1,
wherein two processing units are disposed neighboring each other, and the image pickup device is provided at a position neighboring both of the two processing units, and
wherein the image pickup device captures an image of the arc shape of the outer periphery of the target object when the support arm of the transfer unit is positioned at a predetermined position close to an inlet of one processing unit while supporting the target object, and also captures an image of the arc shape of the outer periphery of the target object when the support arm of the transfer unit is positioned at a predetermined position close to an inlet of the other neighboring processing unit while supporting the target object.

3. The processing apparatus of claim 1,
wherein three or more processing units are disposed neighboring one another, and the image pickup device is provided at a position neighboring the three or more processing units, and
Wherein the image pickup device captures an image of the arc shape of the outer periphery of the target object when the support arm of the transfer unit is positioned at a predetermined position close to an inlet of one processing unit while supporting the target object, captures an image of the arc shape of the outer periphery of the target object when the support arm of the transfer unit is positioned at a predetermined position close to an inlet of another neighboring processing unit while supporting the target object, and captures an image of the arc shape of the outer periphery of the target object when the support arm of the transfer unit is positioned at a predetermined position close to an inlet of still another neighboring processing unit while supporting the target object.

4. The processing apparatus of claim 1, wherein the process in which the image pickup device detects positional data on multiple locations by capturing the image of the arc shape of the outer periphery of the target object and the process in which the calculation unit calculates the central coordinates of the phantom circle of the target object based on the positional data on multiple positions are set as a single sampling process, and the sampling process is performed multiple times.

5. The processing apparatus of claim 1, wherein the image pickup device captures an image of the support arm of the transfer unit, and the calculation unit determines whether or not the target object is mounted on the support arm based on the captured image data.

6. The processing apparatus of claim 1, wherein the image pickup device captures an image of the support arm of the transfer unit, and the calculation unit calculates calibration data of the support arm.

7. The processing apparatus of claim 1, wherein the presence or non-presence of the target object is determined based on the image captured by the image pickup device.

8. The processing apparatus of claim 7, wherein when an edge of the target object is not recognized by the image pickup device, the controller first detects the presence or non-presence of the target object by using the image pickup device, detects a displacement direction of the target object based on the detection result, drives the support arm based on the displacement direction of the target object to position the edge of the target object within a detection range of the image pickup device, obtains a position of the target object by capturing an image of an arc shape corresponding to the edge, next, drives the support arm to position a portion of the target object, that is symmetrical to the detected portion of the target object, within the detection range of the image pickup device, obtains a position of the target object by capturing an image of an arc shape corresponding to the edge of the target object, which corresponds to the symmetrical portion, by the image pickup device, compares the two positions of the target object, and recognizes the obtained position of the target object as a position of the target object when both positions coincide with each other within an allowable range of error.

9. The processing apparatus of claim 7, wherein when an edge of the target object is recognized by the image pickup device at a position where a measurement accuracy is not assured, the controller first obtains a position of the target object by capturing an image of an arc shape corresponding to the edge of the target object by the image pickup device, next, drives the support arm to position the edge of the target object within an area where the measurement accuracy is assured, obtains a position of the target object again by capturing an image of an arc shape corresponding to the edge of the target object by the image pickup device, compares the two positions of the target object, and recognizes the newly obtained position of the target object as a position of the target object when both coincide with each other within an allowable range of error.

10. A processing method of a processing apparatus including at least one processing unit, a transfer unit having a transfer unit for loading and unloading a circular target object to be processed into and from the processing unit, and an image pickup device for capturing an image of an arc shape of an outer periphery of the target object, the method comprising:
detecting positional data on multiple positions by capturing an image of the arc shape of the outer periphery of the target object by the image pickup device when a support arm of the transfer unit is positioned at a predetermined position close to an inlet of the processing unit while supporting the target object;
calculating information on positional displacement of the target object with respect to the transfer unit by obtaining a phantom circle of the target object from the positional data on multiple positions of the arc shape of the target object and calculating central coordinates of the phantom circle; and
controlling the transfer unit based on the information on positional displacement to correct the position of the target object so that the target object is loaded to a predetermined position in the processing unit.

11. The processing method of claim 10,
wherein two processing units are disposed neighboring each other, and the image pickup device is provided at a position neighboring both of the two processing units, and the method comprises:
capturing an image of the arc shape of the outer periphery of the target object by the image pickup device when the support arm of the transfer unit is positioned at a predetermined position close to an inlet of one processing unit while supporting the target object, and capturing an image of the arc shape of the outer periphery of the target object by the image pickup device when the support arm of the transfer unit is positioned at a predetermined position close to an inlet of the other neighboring processing unit while supporting the target object.

12. The processing method of claim 10,
wherein three or more processing units are disposed neighboring one another, and the image pickup device is provided at a position neighboring the three or more processing units, and the method comprises:
capturing an image of the arc shape of the outer periphery of the target object by the image pickup device when the support arm of the transfer unit is positioned at a predetermined position close to an inlet of one processing unit while supporting the target object, capturing an image of the arc shape of the outer periphery of the target object by the image pickup device when the support arm of the transfer unit is positioned at a predetermined position close to an inlet of another neighboring processing unit while supporting the target object, and capturing an image of the arc shape of the outer periphery of the target object by the image pickup device when the support arm of the transfer unit is positioned at a predetermined position close to an inlet of still another neighboring processing unit while supporting the target object.

13. The processing method of claim 10, wherein said detecting positional data on multiple positions by capturing the image of the arc shape of the outer periphery of the target object and said calculating the central coordinates of the phantom circle of the target object are set as a single sampling process, and the sampling process is performed multiple times.

14. The processing method of claim 10, further comprising capturing an image of the support arm of the transfer unit by the image pickup device; and determining whether or not the target object is mounted on the support arm based on the captured image data.

15. The processing method of claim 10, further comprising capturing an image of the support arm of the transfer unit of the target object by the image pickup device; and calculating calibration data of the support arm.

16. A method of recognizing a circular target object to be processed in a processing apparatus including at least one processing unit, a transfer chamber having a transfer unit for loading and unloading the target object into and from the processing unit, and an image pickup device for capturing an image of an edge of the target object when a support arm of the transfer unit is positioned at a predetermined position close to an inlet of the processing unit while supporting the target object, wherein when the edge of the target object is not recognized by the image pickup device in a state where the support arm of the transfer unit which supports the target object is positioned at a predetermined position in the processing unit, the method of recognizing the target object comprises:
detecting the presence or non-presence of the target object by the image pickup device, recognizing a displacement direction of the target object based on the detection result, and driving the support arm based on the displacement direction;
positioning the edge of the target object within a detection range of the image pickup device and obtaining a position of the target object by capturing an image of an arc shape corresponding to the edge of the target object by the image pickup device;
driving the support arm to position a portion of the target object, that is symmetrical to the detected portion of the target object, within the detection range of the image pickup device and obtaining a position of the target object by capturing an image of an arc shape corresponding to the edge, which corresponds to the symmetrical portion, by the image pickup device;
comparing the two positions of the target object; and
recognizing the newly obtained position of the target object as a position of the target object when both positions coincide with each other within an allowable range of error.

17. A method of recognizing a circular target object in a processing apparatus including at least one processing unit, a transfer chamber having a transfer unit for loading and unloading the target object into and from the processing unit, and an image pickup device for capturing an image of an edge of the target object when a support arm of the transfer unit is positioned at a predetermined position close to an inlet of the processing unit while supporting the target object, wherein when the edge of the target object is recognized by the image pickup device at a position where measurement accuracy is not assured in a state where the support arm of the transfer unit which supports the target object is positioned at a predetermined position in the processing unit, the method of recognizing the target object comprises:
obtaining a position of the target object by capturing an image of an arc shape corresponding to the edge of the target object by the image pickup device;
driving the support arm to position the edge of the target object within an area where the measurement accuracy is assured;
obtaining a position of the target object again by capturing an image of an arc shape corresponding to the edge of the target object by the image pickup device;
comparing the two positions of the target object; and
recognizing the newly obtained position as a position of the target object when both positions coincide with each other within an allowable range of error.

18. A computer operable storage medium storing a program for controlling a processing apparatus including at least one processing unit, a transfer chamber having a transfer unit for loading and unloading a circular target object to be processed into and from the processing unit, and an image pickup device for capturing an image of an edge of the target object,
wherein the program, when executed on a computer, controls processing apparatus to perform a processing method including:
detecting positional data on multiple positions by capturing an image of the arc shape of the outer periphery of the target object by the image pickup device when a support arm of the transfer unit is positioned at a predetermined position close to an inlet of the processing unit while supporting the target object;
calculating information on positional displacement of the target object with respect to the transfer unit by obtaining a phantom circle of the target object from the positional data on multiple positions of the arc shape of the target object and calculating central coordinates of the phantom circle; and
controlling the transfer unit based on the information on positional displacement to correct the position of the target object so that the target object is loaded to a predetermined position in the processing unit.

19. A computer operable storage medium storing a program for controlling a processing apparatus including at least one processing unit, a transfer chamber having a transfer unit for loading and unloading a circular target object to be processed into and from the processing unit, and an image pickup device for capturing an image of an edge of the target object when a support arm of the transfer unit is positioned at a predetermined position close to an inlet of the processing unit while supporting the target object,
wherein the program, when executed on a computer, controls the processing apparatus to perform a method of recognizing the target object,
wherein when the edge of the target object is not recognized by the image pickup device in a state where the support arm of the transfer unit which supports the target object is positioned at a predetermined position in the processing unit, the method of recognizing the target object includes:
detecting the presence or non-presence of the target object by the image pickup device, recognizing a displacement direction of the target object based on the detection result, and driving the support arm based on the displacement direction;
positioning the edge of the target object within a detection range of the image pickup device and obtaining a position of the target object by capturing an image of the arc shape corresponding to the edge of the target object by the image pickup device;
driving the support arm to position a portion of the target object, that is symmetrical to the detected portion of the target object, within the detection range of the image pickup device and obtaining a position of the target object by capturing an image of the arc shape corresponding to the edge, which corresponds to the symmetrical portion, by the image pickup device;
comparing the two positions of the target object; and
recognizing the newly obtained position of the target object as a position of the target object when both positions coincide with each other within an allowable range of error.

20. A computer operable storage medium storing a program for controlling a processing apparatus including at least one processing unit, a transfer chamber having a transfer unit for loading and unloading a circular target object to be processed into and from the processing unit, and an image pickup device for capturing an image of an edge of the target object when a support arm of the transfer unit is positioned close to an inlet of the processing unit while supporting the target object,
wherein the program, when executed on a computer, controls the processing apparatus to perform a method of recognizing the target object,
wherein when the edge of the target object is recognized by the image pickup device at a position where measurement accuracy is not assured in a state where the support arm of the transfer unit which supports the target object is positioned at a predetermined position in the processing unit, the method of recognizing the target object includes:
obtaining a position of the target object by capturing an image of an arc shape corresponding to the edge of the target object by the image pickup device;
driving the support arm so as to position the edge of the target object within an area where the measurement accuracy is assured;
obtaining a position of the target object again by capturing an image of an arc shape corresponding to the edge of the target object by the image pickup device;
comparing the two positions of the target object; and
recognizing the newly obtained position of the target object as a position of the target object when both positions coincide with each other within an allowable range of error.
